(19) United States
(12) Patent Application Publication
(10) Pub. No.: US 2009/0090989 A1
(43) Pub. Date: Apr. 9, 2009

(54) Image Sensor and Method of Manufacturing the Same

(76) Inventor: Chang Hun HAN, Icheon-si (KR)

Correspondence Address: SALIWANCHIK LLOYD & SALIWANCHIK;A PROFESSIONAL ASSOCIATION, PO Box 142950, GAINESVILLE, FL, 32614, US

(21) Appl. No.: 12/241,247

(22) Filed: Sep. 30, 2008

(30) Foreign Application Priority Data
Oct. 4, 2007 (KR) 10-2007-0099610

(51) Int. Cl. H01L 31/0232; H01L 21/28

(52) U.S. Cl. 257/432; 438/70; 257/E31.127; 257/E21.158

(57) ABSTRACT

An image sensor and a manufacturing method thereof are provided. The image sensor can comprise: a semiconductor substrate, a first dielectric, a second dielectric pattern, a planarization layer, and a color filter. The semiconductor substrate comprises a photodiode. The first dielectric is disposed on the semiconductor substrate. The second dielectric pattern is disposed on the first dielectric and comprises a trench in a region corresponding to the photodiode. The planarization layer is disposed in the trench. The color filter is disposed on the planarization layer disposed on the photodiode.

### CROSS-REFERENCE TO RELATED APPLICATION

The present application claims the benefit under 35 U.S.C. § 119 to Korean Patent Application No. 10-2007-0099610, filed Oct. 4, 2007, which is hereby incorporated by reference in its entirety.

### BACKGROUND

An image sensor is a semiconductor device that converts an optical image into an electrical signal. An image sensor is generally classified as either a charge coupled device (CCD) image sensor or a complementary metal oxide semiconductor (CMOS) image sensor (CIS).

Each unit pixel of a CMOS image sensor typically includes a photodiode and a metal oxide semiconductor (MOS) transistor. The CMOS image sensor sequentially detects an electrical signal of the unit pixel in a switching manner to generate an image.

A CMOS image sensor often includes a pixel array, a metal interconnection layer, a color filer, and a microlens. The pixel array includes a transistor and a photodiode, and the metal interconnection layer includes a plurality of interconnections on the pixel array.

As a design rule in CMOS image sensors continues to decrease, the size of each unit pixel is decreased, which can lead to reduced photosensitivity of the photodiode. Also, since the metal interconnection layer is often provided in a multi-layered structure, the light absorption rate of the photodiode can be further reduced.

### BRIEF SUMMARY

Embodiments of the present invention provide an image sensor and a manufacturing method thereof that can improve the sensitivity of a photodiode.

In one embodiment, an image sensor can comprise: a semiconductor substrate comprising a photodiode; a first dielectric on the semiconductor substrate; a second dielectric pattern on the first dielectric; a trench at a side of the second dielectric pattern, wherein at least a portion of the trench is over the photodiode; a planarization layer in the trench; and a color filter on the planarization layer.

In another embodiment, a method of manufacturing an image sensor can comprise: forming a photodiode in a semiconductor substrate; forming a first dielectric on the semiconductor substrate including the photodiode; forming a second dielectric pattern on the first dielectric; forming a second trench at a side of the second dielectric pattern, wherein at least a portion of the second trench is over the photodiode; forming a planarization layer in the trench; and forming a color filter on the planarization layer.

The details of one or more embodiments are set forth in the accompanying drawings and the description below. Other features will be apparent to a skilled artisan from the detailed description, the drawings, and the claims.

### BRIEF DESCRIPTION OF THE DRAWINGS

FIGS. 1 to 8 are cross-sectional views showing a process of manufacturing an image sensor according to an embodiment of the present invention.

### DETAILED DESCRIPTION

An image sensor and a manufacturing method thereof according to embodiments of the present invention will now be described in detail with reference to the accompanying drawings.

When the terms “on” or “over” or “above” are used herein, when referring to layers, regions, patterns, or structures, it is understood that the layer, region, pattern, or structure can be directly on another layer or structure, or intervening layers, regions, patterns, or structures may also be present. When the terms “under” or “below” are used herein, when referring to layers, regions, patterns, or structures, it is understood that the layer, region, pattern, or structure can be directly under the other layer or structure, or intervening layers, regions, patterns, or structures may also be present.

FIG. 8 is a cross-sectional view showing an image sensor according to an embodiment.

Referring to FIG. 8, an image sensor can include a semiconductor substrate 10, a first dielectric 40, a second dielectric pattern 65, a planarization layer 90, and a color filter 100. The semiconductor substrate 10 can include a photodiode 30. The first dielectric 40 can be disposed on the semiconductor substrate 10 including the photodiode 30. The second dielectric pattern 65 can be disposed on the first dielectric 40, and a second trench 63 can be provided over the photodiode 30. The planarization layer 90 can be disposed in the second trench 63. The color filter 100 can be disposed on the planarization layer 90 over the photodiode 30.

The first dielectric 40 can be formed of any suitable material known in the art. In an embodiment, the first dielectric 40 can be formed of a silane (SiH₄) material including hydrogen. The first dielectric 40 can help protect the semiconductor substrate 10 from damage when the second trench 63 is formed.

The second dielectric pattern 65 can include a plurality of interlayer dielectrics. A plurality of metal interconnections 70 can be disposed in the second dielectric pattern 65. The second dielectric pattern 65 including the metal interconnections 70 can be formed such that it is not over the photodiode 30. In addition, the second trench 63 can be disposed such that at least a portion of the second trench 63 is over the photodiode 30.

A first mask pattern 55 can be disposed under the second dielectric pattern 65. A second mask pattern 85 can be disposed on a top surface and side surfaces of the second dielectric pattern 65. Thus, the second mask pattern 85 can be disposed on an outer surface of the second dielectric pattern 65. In an embodiment, the first mask pattern 55 and the second mask pattern 85 can be formed of a nitride.

In one embodiment, the planarization layer 90 can be formed of a photosensitive material.

Accordingly, the first mask pattern 55 and the second mask pattern 85 can be disposed around only the second dielectric pattern 65. The planarization layer 90 can be disposed in the second trench 63 on the photodiode 30. Thus, diffused reflection and the refraction of light incident to the photodiode 30 can be inhibited, and the sensitivity of the image sensor can be improved.

Also, the first dielectric 40 can be disposed on the semiconductor substrate 10 to help inhibit plasma damage that may occur during etching. The occurrence of a dangling bond that may be formed on a surface of the semiconductor substrate 10 can be inhibited, thereby improving dark characteristics of the image sensor.

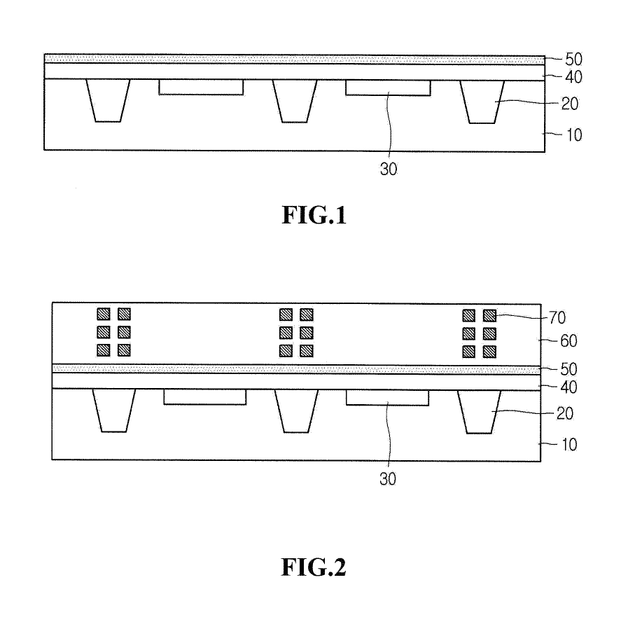

A method of manufacturing an image sensor according to an embodiment will now be described with reference to FIGS. 1 to 8.

Referring to FIG. 1, a device isolation region 20 defining an active region and a field region can be formed on a semiconductor substrate 10. A unit pixel can be provided in the active region.

The unit pixel can include a photodiode 30 for receiving light to generate photoelectric charges and complementary metal oxide semiconductor (CMOS) circuitry (not shown) electrically connected to the photodiode 30 for converting the photoelectric charges into electric signals.

A first dielectric 40 can formed on the semiconductor substrate 10 after forming the photodiode 30 and the CMOS circuitry (not shown). The first dielectric 40 can be formed of any suitable material known in the art, for example, a silane (SiH₄)-based material including hydrogen. In embodiments in which the first dielectric 40 is formed of a silane-based material, the first dielectric 40 can help protect the semiconductor substrate 10 during a subsequent dielectric etching process. Also, the first dielectric 40 can help inhibit a dangling bond which may occur due to a surface defect of the semiconductor substrate 10, thereby improving the dark characteristics of the image sensor.

A first mask 50 can be formed on the first dielectric 40. The first mask 50 can be formed of any suitable material known in the art. In one embodiment, the first mask 50 can be formed of a nitride to serve as an etch stop layer during a subsequent etching process.

Referring to FIG. 2, a second dielectric 60 including metal interconnections 70 can be formed on the first mask 50. In an embodiment, the second dielectric 60 can include a plurality of interlayer dielectrics, and the metal interconnections 70 can include a plurality of layers.

The metal interconnections 70 can include a plurality of layers to connect a power line or a signal line to a unit pixel and a peripheral circuitry. The metal interconnections 70 can be formed such that they are not directly over the photodiode 30, thereby inhibiting the metal interconnections 70 from blocking light incident to the photodiode 30. Thus, a portion of the second dielectric 60 that does not include the metal interconnections 70 can be disposed over the photodiode 30.

In an embodiment, the second dielectric 60 can be formed of an oxide. The metal interconnections 70 can be formed of, for example, a metal, an alloy, silicide, aluminum, copper, cobalt, or tungsten.

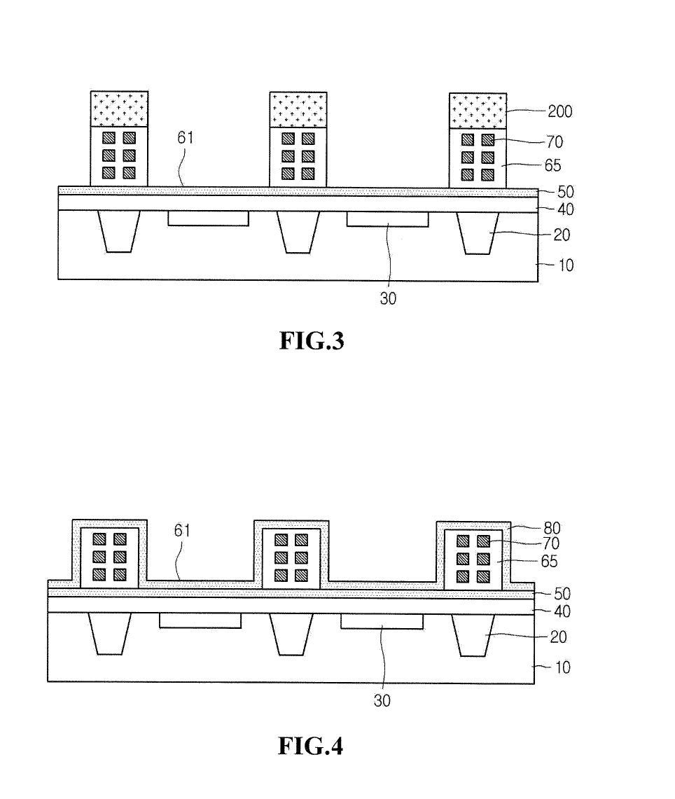

Referring to FIG. 3, a first trench 61 can be formed in the second dielectric 60. The first trench 61 can expose a portion of the first mask 50 disposed over the photodiode 30. In an embodiment, a first trench 61 can be formed in each unit pixel.

In an embodiment, in order to form the first trench 61, a first photoresist pattern 200 can be formed, exposing a surface of the second dielectric 60 over the photodiode 30. Then, the second dielectric 60 can be etched using the first photoresist pattern 200 as an etch mask. At this point, the first mask 50 can be used as an etch stop layer during the etching of the second dielectric 60, thereby inhibiting etching of the first dielectric 40.

Accordingly, the first trench 61 can be formed to expose a surface of the first mask 50 over the photodiode 30, thereby forming the second dielectric pattern 65 including the metal interconnections 70.

Referring to FIG. 4, a second mask 80 can be formed on the second dielectric pattern 65 and in the first trench 61. The second mask 80 can be formed on a top surface and the side surfaces of the second dielectric pattern 65 and in the first trench 61. The second mask 80 can serve as a passivation layer for the second dielectric pattern 65. The second mask 80 can be formed of any suitable material known in the art, for example, a nitride.

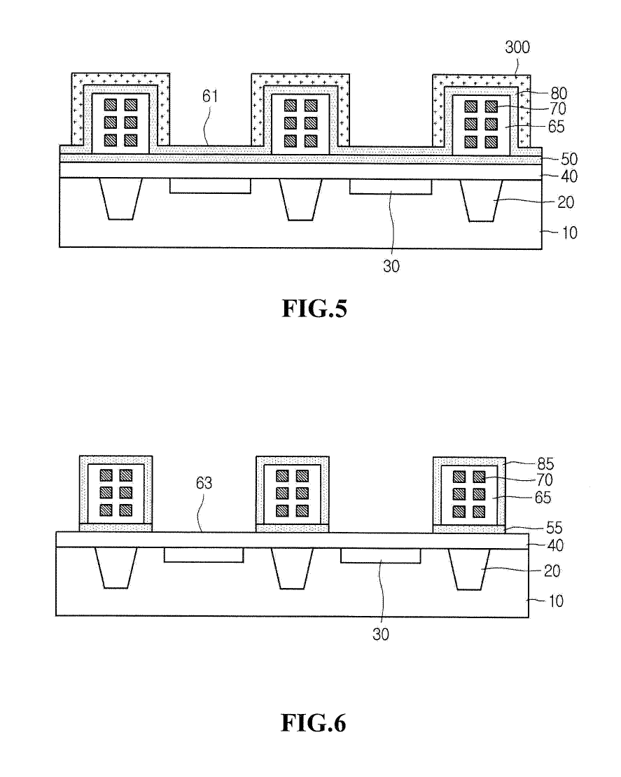

Referring to FIG. 5, a second photoresist pattern 300 can be formed on the second mask 80. The second photoresist pattern 300 can be formed to shield the second dielectric pattern 65 including the metal interconnections 70, while exposing a surface of the second mask 80 in the first trench 61 and over the photodiode 30.

Referring to FIG. 6, the first mask 50 and the second mask 80 can be etched using the second photoresist pattern 300 as an etch mask. Thus, a second trench 63 exposing the first dielectric 40 can be formed over the photodiode 30. Also, the first mask pattern 55 can remain under the second dielectric pattern 65, and the second mask pattern 85 can remain on the side surfaces of the second dielectric pattern 65.

Accordingly, the first mask 50 and the second mask 80 disposed over the photodiode 30 can be removed to inhibit diffused reflection and refraction of light incident to the photodiode 30, thereby improving the optical characteristics of the image sensor.

When etching the first mask 50 and the second mask 80, the first dielectric 40 can help protect the surface of the semiconductor substrate 10 to inhibit defects that may occur during the etching.

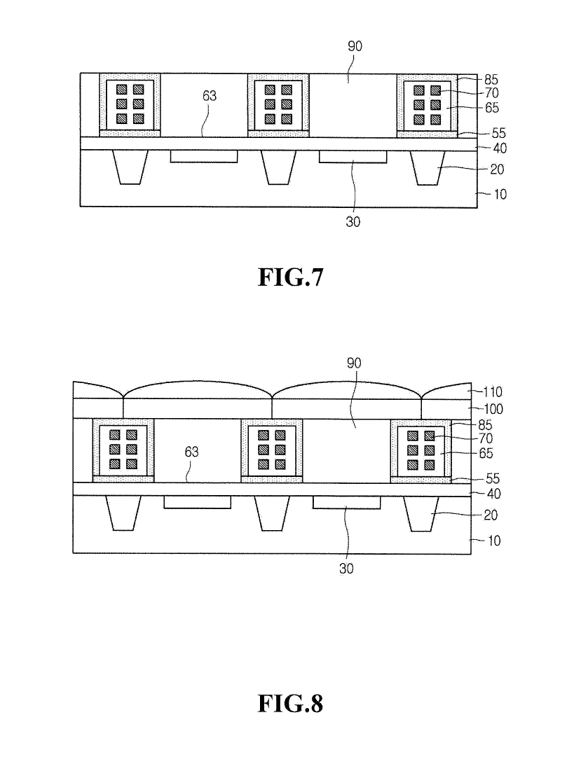

Referring to FIG. 7, the planarization layer 90 can be formed in the second trench 63. The planarization layer 90 can provide a substantially planar surface on the semiconductor substrate 10 for forming color filter 100 during a subsequent process.

In an embodiment, the planarization layer 90 can be formed by depositing an insulating material on the semiconductor substrate 10 and in the second trench 63 and then performing a planarization process. For example, the planarization layer 90 can be formed by depositing a photosensitive material on the semiconductor substrate 10 and performing a chemical mechanical polishing (CMP) process using an upper surface of the second mask pattern 85 as a polishing stop point.

Although not shown, in an embodiment, a passivation layer can be formed on the second mask pattern 85 and the planarization layer 90 through a subsequent process to help protect the device from moisture or scratching.

Referring to FIG. 8, the color filter 100 can be formed on the second mask pattern 85 and the planarization layer 90.

In an embodiment, the color filter 100 can be formed by depositing a color filter material (not shown) on the semiconductor substrate 10, and then exposing the color filter material to light through a pattern mask (not shown) and developing the color filter material. The color filter material can include, for example, a photosensitive material and a pigment or a photosensitive material and a dye.

The color filter 100 can be formed over the photodiode 30 to correspond to a unit pixels, and can serve to separate colors from incident light. For example, the color filter 100 can be a red color filter, a green color filter, or a blue color filter.

Then, a microlens 110 can be formed on the color filter 100. In an embodiment, the microlens 110 can be provided in an angled microlens pattern corresponding to the unit pixel by applying a silicon oxide-based photosensitive photoresist having a high light-transmittance, and then performing a patterning process. Then, a reflow process can be performed to form the microlens 110 in a dome shape. In an alternative embodiment, the microlens 110 can be formed as a low temperature oxide layer.

According to methods of manufacturing an image sensor of the present invention, the planarization layer 90 can be formed of a photosensitive material over the photodiode 30 to inhibit the reflection and refraction of light incident to the photodiode 30. Accordingly, a light absorption rate of the photodiode 30 can be increased, thereby improving the sensitivity of the image sensor.

Also, the first dielectric 40 can be formed of a silane material on the semiconductor substrate 10 including the photodiode 30, thereby inhibiting a surface defect of the semiconductor substrate 10. Furthermore, a dangling bond that may occur due to the surface defect can be inhibited, thereby improving the dark characteristics of the image sensor.

According to embodiments of the present invention, the planarization layer can be formed of a photosensitive material over the photodiode, thereby improving the light absorption rate.

The dielectric can be formed of a silane material on the surface of the semiconductor substrate including the photodiode, thereby inhibiting a defect in the semiconductor substrate.

Additionally, the occurrence of a dangling bond due to a surface defect in the semiconductor substrate can be inhibited, thereby improving the dark characteristics of the image sensor.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An image sensor comprising:
a semiconductor substrate comprising a photodiode;
a first dielectric on the semiconductor substrate;
a second dielectric pattern on the first dielectric
a trench at a side of the second dielectric pattern, wherein at least a portion of the trench is over the photodiode;
a planarization layer in the trench; and
a color filter on the planarization layer.

2. The image sensor according to claim 1, wherein the first dielectric comprises a silane (SiH₄) material.

3. The image sensor according to claim 1, further comprising:
a first mask pattern on the first dielectric and under the second dielectric pattern; and
a second mask pattern on an outer surface of the second dielectric pattern.

4. The image sensor according to claim 3, wherein the first mask pattern comprises a nitride material, and wherein the second mask pattern comprises a nitride material.

5. The image sensor according to claim 1, wherein the planarization layer comprises a photosensitive material.

6. The image sensor according to claim 1, wherein the second dielectric pattern is provided such that no portion of the second dielectric pattern is over the photodiode.

7. The image sensor according to claim 1, further comprising a microlens on the color filter.

8. The image sensor according to claim 1, wherein the second dielectric pattern comprises a plurality of metal interconnections.

9. A method of manufacturing an image sensor, comprising:
forming a photodiode in a semiconductor substrate;
forming a first dielectric on the semiconductor substrate including the photodiode;
forming a second dielectric pattern on the first dielectric,
forming a second trench at a side of the second dielectric pattern, wherein at least a portion of the second trench is over the photodiode;
forming a planarization layer in the trench; and
forming a color filter on the planarization layer.

10. The method according to claim 9, wherein the first dielectric comprises a silane (SiH₄) material.

11. The method according to claim 9, wherein the second dielectric pattern comprises a plurality of metal interconnections formed therein.

12. The method according to claim 9, wherein forming the second dielectric pattern and the second trench comprises:
forming a first mask on the first dielectric;
forming a second dielectric, and a plurality of metal interconnections therein, on the first mask;
removing a portion of the second dielectric over the photodiode to form the second dielectric pattern and a first trench at a side of the second dielectric pattern;
forming a second mask on the second dielectric pattern; and
removing a portion of the first mask and a portion of the second mask over the photodiode to form the second trench.

13. The method according to claim 12, wherein the first mask comprises a nitride material, and wherein the second mask comprises a nitride material.

14. The method according to claim 12, wherein a remaining portion of the first mask forms a first mask pattern on the first dielectric and under the second dielectric pattern, and wherein a remaining portion of the second mask forms a second mask pattern on an outer surface of the second dielectric pattern.

15. The method according to claim 9, wherein the planarization layer comprises a photosensitive material.

16. The method according to claim 9, wherein forming the planarization layer comprises:
depositing a photosensitive material in the second trench; and
performing a chemical mechanical polishing process on the photosensitive material to form the planarization layer.

17. The method according to claim 16, further comprising forming a second mask pattern on an outer surface of the second dielectric pattern, wherein the second mask pattern is used as a polishing stop point during the chemical mechanical polishing process.

18. The method according to claim 9, wherein the second dielectric pattern is formed such that no portion of the second dielectric pattern is over the photodiode.

19. The method according to claim 9, further comprising forming a microlens on the color filter.

20. The method according to claim 9, further comprising forming a passivation layer on the planarization layer before forming the color filter.
